(19) United States
(12) Patent Application Publication
(10) Pub. No.: US 2023/0096934 A1
(43) Pub. Date: Mar. 30, 2023

(54) INTEGRATED CIRCUIT POST-LAYOUT SIMULATION METHOD AND DEVICE, ELECTRONIC DEVICE AND STORAGE MEDIUM

(71) Applicant: CHANGXIN MEMORY TECHNOLOGIES, INC., Hefei City (CN)

(72) Inventor: Shao YOU, Hefei (CN)

(21) Appl. No.: 17/826,237

(22) Filed: May 27, 2022

(30) Foreign Application Priority Data
Sep. 28, 2021 (CN) 202111143373.0

(51) Int. Cl. G06F 30/323

(52) U.S. Cl. CPC G06F 30/323

(57) ABSTRACT

An integrated circuit post-layout simulation method and device, an electronic device and a storage medium are provided and belong to the technical field of semiconductors. The integrated circuit post-layout simulation method includes: acquiring a pre-layout simulation netlist of a to-be-simulated circuit; acquiring a first parasitic netlist of a target sub-element in the to-be-simulated circuit; acquiring a simulation netlist of the to-be-simulated circuit using the first parasitic netlist and the pre-layout simulation netlist; and simulating the simulation netlist.

### CROSS-REFERENCE TO RELATED APPLICATION

This application claims priority to Chinese patent application No. 202111143373.0, filed on Sep. 28, 2021, the disclosure of which is hereby incorporated by reference in its entirety.

### BACKGROUND

With the development of process, influences of parasitics such as parasitic capacitance on the performance of an integrated circuit cannot be ignored any longer, especially for the design of a deep-submicron integrated circuit. At present, a post-layout simulation test is adopted to test whether a circuit with parasitic capacitance meets the design requirements.

“Post-layout simulation” refers to that after design of layout is completed, the circuit design of a layout is transformed into a simulated circuit for simulation to obtain a circuit parameter netlist and parasitic parameter netlist of the simulated circuit; and the parasitic parameters in the parasitic parameter netlist, such as parasitic capacitance parameters, are labelled into the extracted circuit parameter netlist for simulation, so as to analyzed the circuit to ensure that the circuit meets the design requirements.

With the increasing scale of the integrated circuit, the number of transistors on a chip has been increasing, which leads to the rapid expansion of the number of parasitic resistors and capacitors, and increased time needed for circuit post-layout simulation. The circuit verification time is longer, which affects the design cycle of the chip and the delivery time of a product to a certain extent.

### SUMMARY

The disclosure relates to the technical field of semiconductors, in particular to an integrated circuit post-layout simulation method and device, an electronic device and a storage medium.

In a first aspect of embodiment of the disclosure, provided is an integrated circuit post-layout simulation method, which may include: acquiring a pre-layout simulation netlist of a to-be-simulated circuit; acquiring a first parasitic netlist of a target sub-element in the to-be-simulated circuit; acquiring a simulation netlist of the to-be-simulated circuit using the first parasitic netlist and the pre-layout simulation netlist; and simulating the simulation netlist.

In a second aspect of embodiments of the disclosure, provided is an integrated circuit post-layout simulation device, which may include: a processor, a memory, and a program or instructions stored in the memory and executable in the processor, wherein the program or instructions, when executed by the processor, cause the processor to execute operations of: acquiring a pre-layout simulation netlist of a to-be-simulated circuit; acquiring a first parasitic netlist of a target sub-element in the to-be-simulated circuit; acquiring a simulation netlist of the to-be-simulated circuit using the first parasitic netlist and the pre-layout simulation netlist; and simulating the simulation netlist.

In a third aspect of embodiments of the disclosure, provided is a chip, including a processor and a communication interface coupled to the processor. The processor is configured to run a program or instructions to implement an integrated circuit post-layout simulation method, including operations of: acquiring a pre-layout simulation netlist of a to-be-simulated circuit; acquiring a first parasitic netlist of a target sub-element in the to-be-simulated circuit; acquiring a simulation netlist of the to-be-simulated circuit using the first parasitic netlist and the pre-layout simulation netlist; and simulating the simulation netlist.

### BRIEF DESCRIPTION OF THE DRAWINGS

FIG. 1 illustrates a flowchart of an integrated circuit post-layout simulation method according to an exemplary embodiment of the disclosure.

FIG. 2 illustrates a schematic diagram of a pre-layout simulation netlist according to an exemplary embodiment of the disclosure.

FIG. 3 illustrates a schematic diagram of a simulation netlist according to an exemplary embodiment of the disclosure.

FIG. 4 illustrates a schematic structural diagram of an integrated circuit post-layout simulation device according to an exemplary embodiment of the disclosure.

FIG. 5 illustrates a schematic structural diagram of an electronic device according to an exemplary embodiment of the disclosure.

FIG. 6 illustrates a schematic structural diagram of hardware of an electronic device according to an exemplary embodiment of the disclosure.

### DETAILED DESCRIPTION

In order to make the objectives, technical solution and advantages of the disclosure to be understood more clearly, the disclosure is described in further detail below with reference to the drawings. It should be understood that the description is merely illustrative and is not intended to limit the scope of the disclosure. Further, in the following description, the description of well-known structures and art is omitted to avoid unnecessarily confusing the concepts of the disclosure.

The schematic diagram of a layer structure according to the embodiments of the disclosure is illustrated in the drawings. The drawings are not drawn to scale, in which some details are enlarged and may be omitted for clarity. The shapes of the various regions, layers and the relative sizes and positional relationships therebetween shown in the drawings are merely illustrative and may vary in practice due to manufacturing tolerances or technical limitations, and those skilled in the art may additionally design regions/layers having different shapes, sizes, relative positions according to actual needs.

It is apparent that the described embodiments are part of and not all of the embodiments of the disclosure. Based on the embodiments of the disclosure, all other embodiments obtained by those of ordinary skill in the art without making creative efforts should fall within the scope of the disclosure.

In the description of the disclosure, it should be noted that the terms “first”, “second”, “third” are merely for description and should not be understood to indicate or imply relative importance.

Further, the technical features described below involved embodiments of the disclosure may be combined with each other without conflict.

In existing technologies of post-layout simulation, due to that the top-layer circuit has a large scale and numerous parasitic parameters, it costs long time to perform simulation. The inventor found that in fact, some circuit sub-modules do not need to be verified in many cases, but all circuit modules have to be simulated without being able to skip the modules, which leads to too long post-layout simulation time. In this regard, the disclosure provides an integrated circuit post-layout simulation method to solve the problem.

The integrated circuit post-layout simulation method according to the embodiments of the disclosure will be described in detail with reference to the drawings through specific embodiments and application scenes thereof.

The technical solution of the disclosure has the following beneficial effects.

In the method according to the embodiments of the disclosure, a pre-layout simulation netlist of a to-be-simulated circuit is acquired, a first parasitic netlist of a target sub-element in the to-be-simulated circuit is acquired, a simulation netlist of the to-be-simulated circuit is acquired using the first parasitic netlist and the pre-layout simulation netlist, and the simulation netlist is simulated. In the method, simulation is performed by covering the pre-layout simulation netlist with the parasitic parameters of the target sub-element, and the circuit modules which do not need to be verified are omitted. The simulation can be carried out more pertinently, reducing the simulation time, and improving the simulation speed and verification efficiency of the integrated circuit.

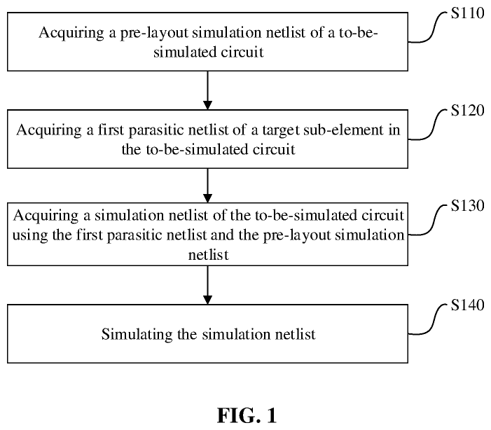

As illustrated in FIG. 1, in a first aspect, embodiments of the disclosure provide an integrated circuit post-layout simulation method, which may include the following steps:

S110: a pre-layout simulation netlist of a to-be-simulated circuit is acquired.

S120: a first parasitic netlist of a target sub-element in the to-be-simulated circuit is acquired.

S130: a simulation netlist of the to-be-simulated circuit is acquired using the first parasitic netlist and the pre-layout simulation netlist.

S140: the simulation netlist is simulated.

In the method provided in the embodiment, in the simulation, the pre-layout simulation netlist is covered with the parasitic parameters of the target sub-element, omitting circuit modules which do not need to be verified. The simulation can be carried out more pertinently, reducing the simulation time, and improving the simulation speed and verification efficiency of the integrated circuit.

For clearer description, the foregoing steps will be described respectively below.

Step S110 of acquiring the pre-layout simulation netlist of the to-be-simulated circuit is described.

In this step, the correctness of the logical connection relationship in the circuit may be analyzed according to the pre-layout simulation netlist. The simulation speed is fast, and the waveform at an input and output port of the circuit, the waveform of any signal inside the circuit, and the waveform of the register may be observed as required.

Next, step S120 of acquiring the first parasitic netlist of the target sub-element in the to-be-simulated circuit is described.

In this step, the target sub-element may be a circuit module which must be verified during simulation. In this way, the modules which do not need to be verified but cannot be skipped in the related art can be removed. By skipping the modules which do not need to be verified, the post-layout simulation time can be reduced. The target sub-element may also be a circuit module which has been completed during circuit layout design. Therefore, the completed circuit modules may be simulated firstly before the layout design of the top layer is completed, so as to speed up the project progress.

Next, step S130 of acquiring the simulation netlist of the to-be-simulated circuit using the first parasitic netlist and the pre-layout simulation netlist is described.

In this step, the simulation netlist may be obtained by using a first parasitic netlist corresponding to each target sub-element of multiple target sub-elements to cover a sub-element in the pre-layout simulation netlist corresponding to the target sub-element to.

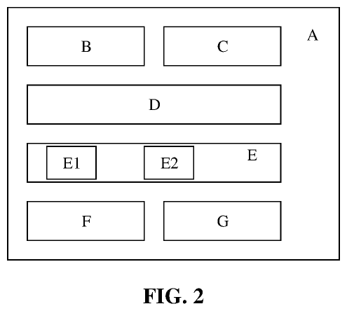

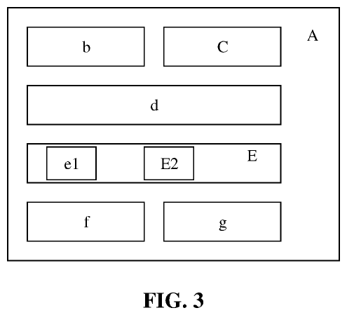

Exemplarily, before the pre-layout simulation netlist is covered, as illustrated in FIG. 2, A is the top layer circuit, and B/C/D/E/F/G are all target sub-elements. E1/E2 are sub-elements of E. The target sub-elements B/D/E1/F/G in the pre-layout simulation netlist of the top layer circuit are covered with the parasitic netlists. The parasitic parameters of B/D/E1/F/G may be extracted in batches firstly, and then the Pin definition of the parasitic netlists of B/D/E1/F/G are replaced with the Pin definition of the pre-layout simulation netlist, thereby forming the simulation netlist. As illustrated in FIG. 3, b/d/e1/f/g are elements with the parasitic parameters.

Finally, the step S140 of simulating the simulation netlist is described.

In this step, a simulator may be called to run the simulation netlist directly, to obtain simulation results quickly.

According to an embodiment, before acquiring the first parasitic netlist of the target sub-element in the to-be-simulated circuit, the integrated circuit post-layout simulation method may further include: determining the target sub-element in the to-be-simulated circuit.

According to an embodiment, acquiring the first parasitic netlist of the target sub-element in the to-be-simulated circuit may include: exporting a class definition language (CDL) netlist of the target sub-element; determining a layout structure of the target sub-element and exporting a graphic data system (GDS) file according to the layout structure; and obtaining the first parasitic netlist according to the CDL netlist and the GDS file.

According to an embodiment, obtaining the first parasitic netlist according to the CDL netlist and the GDS file may include: inputting the CDL netlist and GDS file into an electronic design automation (EDA) tool, to enable the EDA tool to output the first parasitic netlist.

According to an embodiment, acquiring the simulation netlist of the to-be-simulated circuit using the first parasitic netlist and the pre-layout simulation netlist may include: changing an interface definition in the first parasitic netlist to obtain a second parasitic netlist. The second parasitic netlist can be called by the pre-layout simulation netlist. The simulation netlist includes the second parasitic netlist and the pre-layout simulation netlist.

By means of the method provided in the embodiments, the circuit elements which do not need to be verified can be skipped, to reduce the post-layout simulation time. Moreover, the completed circuit modules may be simulated firstly before the layout design of the top layer is completed, so as to speed up the project progress. In the implementations of the embodiments, the interface definition in the first parasitic netlist may be replaced with the interface definition in the pre-layout simulation netlist to form a second parasitic netlist. Since the interface definition is changed into the interface definition in the pre-layout simulation netlist, the second parasitic netlist may be called by the pre-layout simulation netlist.

Exemplarily, the process of acquiring the second parasitic netlist may be implemented in the following way:

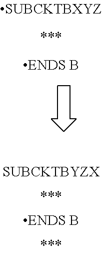

In the implementation of the foregoing embodiments, the interface definition X Y Z of the sub-element B in the first parasitic netlist is replaced with the interface definition Y Z X in the pre-layout simulation file corresponding to the sub-element B, to form the second parasitic netlist of the sub-element B. Thus, the second parasitic netlist may be directly called during simulation.

In an embodiment, a pre-layout simulation netlist may include a pre-layout simulation sub-netlist corresponding to a target sub-element, and the interface definition of the second parasitic netlist may be the same as that of the pre-layout simulation sub-netlist.

In an embodiment, simulating the simulation netlist may include: importing the simulation netlist into a simulator; and calling the simulator to simulate the simulation netlist.

An exemplary embodiment of the disclosure provides an integrated circuit post-layout simulation method, which may include: exporting a pre-layout simulation netlist of a top layer circuit, extracting parasitic parameters of multiple sub-elements in batches, replacing the interface definition of a post-layout simulation netlist of each element with the interface definition of a pre-layout simulation netlist in batches, enabling the pre-layout simulation netlist of the top layer circuit and the parasitic netlist of each sub-element to be contained in a simulation netlist, and simulating the simulation netlist.

As illustrated in FIG. 3, the simulation netlist may include the parasitic netlist and the pre-layout simulation netlist. In the implementation, a netlist (a testbench, the netlist may run directly in the simulator) including all data and parameter configurations is enable to include the second parasitic netlist and the pre-layout simulation netlist to form the simulation netlist. During simulation of the simulation netlist, the second parasitic netlist will be called when running into the target sub-element, thereby achieving the post-layout simulation of the circuit.

Exemplarily, the simulation netlist including all the data and parameter configurations being enabled to include the second parasitic netlist and the pre-layout simulation netlist may be implemented in the following way:

.inc A.sp
.inc b.spf
.inc d.spf
.inc e1.spf
.inc g.spf
***

Herein, .sp refers to spice netlist, which is a circuit netlist without parasitic parameters, and may be used for pre-layout simulation; .spf, i.e., spef (Standard Parasitic Exchange Format) refers to a standard medium file that transmits parasitic parameters of interconnecting lines between EDA tools in integrated circuit design process; and .inc refers to a netlist including the parasitic parameters, and is used for post-layout simulation. In the implementation, the pre-layout simulation netlist A.sp and second parasitic netlists b.spf, d.spf, e1.spf, and g.spf are enabled to be included in the simulation netlist to form the input.sp. Thus the simulation netlist can be simulated to realize fast post-layout simulation of the integrated circuit.

It should be noted that, the integrated circuit post-layout simulation method provided in the embodiments of the disclosure may be executed by an integrated circuit post-layout simulation device or a control module in the integrated circuit post-layout simulation device for executing the integrated circuit post-layout simulation method. In the embodiments of the disclosure, the integrated circuit post-layout simulation device according to the embodiments of the disclosure will be described with the integrated circuit post-layout simulation device executing the integrated circuit post-layout simulation method as an example.

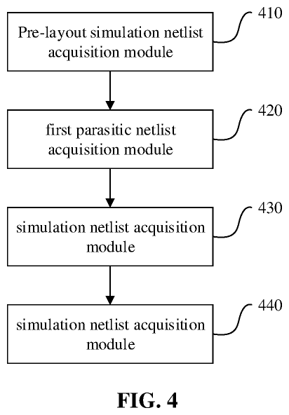

As illustrated in FIG. 4, in a second aspect of embodiments of the disclosure provided is an integrated circuit post-layout simulation device, which may include a pre-layout simulation netlist acquisition module 410, a first parasitic netlist acquisition module 420, a simulation netlist acquisition module 430 and a simulation module 440.

The pre-layout simulation netlist acquisition module 410 is configured to acquire a pre-layout simulation netlist of a to-be-simulated circuit. The first parasitic netlist acquisition module 420 is configured to acquire a first parasitic netlist of a target sub-element in the to-be-simulated circuit. The simulation netlist acquisition module 430 is configured to acquire a simulation netlist of the to-be-simulated circuit using the first parasitic netlist and the pre-layout simulation netlist. The simulation module 440 is configured to simulate the simulation netlist.

According to the device provided in the embodiment, simulation may be performed by means that a parasitic parameter covering module covers the pre-layout simulation netlist with the parasitic parameters of the target sub-element, omitting the circuit modules which do not need to be verified. The simulation can be carried out more pertinently, reducing the simulation time, and improving the simulation speed and verification efficiency of the integrated circuit.

According to an embodiment, the integrated circuit post-layout simulation device may further include a target sub-element determination module. The target sub-element determination module is configured to determine the target sub-element in the to-be-simulated circuit.

According to an embodiment, the first parasitic netlist acquisition module may include: a class definition language (CDL) netlist export unit, a graphic data system (GDS) file export unit, and a first parasitic netlist acquisition unit.

The CDL netlist export unit is configured to export a CDL netlist of the target sub-element. The GDS file export unit is configured to determine a layout structure of the target sub-element and export a graphic data system (GDS) file according to the layout structure. The first parasitic netlist acquisition unit is configured to obtain the first parasitic netlist according to the CDL netlist and the GDS file.

According to an embodiment, the first parasitic netlist acquisition unit may be configured to input the CDL netlist and the GDS file into an electronic design automation (EDA) tool, to enable the EDA tool to output a first parasitic netlist.

According to an embodiment, the simulation netlist acquisition module may be configured to change an interface definition in a first parasitic netlist to obtain a second parasitic netlist. The second parasitic netlist can be called by a pre-layout simulation netlist, and the simulation netlist includes the second parasitic netlist and the pre-layout simulation netlist.

According to an embodiment, the simulation module may include: a simulation netlist import unit and a calling unit.

The simulation netlist import unit is configured to import a simulation netlist into a simulator, and the calling unit is configured to call the simulator to simulate the simulation netlist.

The integrated circuit post-layout simulation device according to the embodiments of the disclosure may be a device, or may be a component, an integrated circuit, or a chip in a terminal. The device may be a mobile electronic device or a non-mobile electronic device. Exemplarily, the mobile electronic device may be a mobile phone, a tablet computer, a notebook computer, a palmtop computer, a vehicle-mounted electronic device, a wearable device, a Ultra-Mobile Personal Computer (UMPC), a netbook or a Personal Digital Assistant (PDA), etc. The non-mobile electronic device may be a server, a Network Attached Storage (NAS), a Personal Computer (PC), a Television (TV), an Automatic Teller Machine (ATM) or a self-service machine, which is not specifically limited herein.

The integrated circuit post-layout simulation device according to the embodiments of the disclosure may be a device with an operating system. The operating system may be an Android operating system, an IOS operating system, and other possible operating systems, which is not specifically limited herein.

The integrated circuit post-layout simulation device according to the embodiments of the disclosure may be configured to implement process according to the method embodiment illustrated in FIG. 1, which will not be repeated herein.

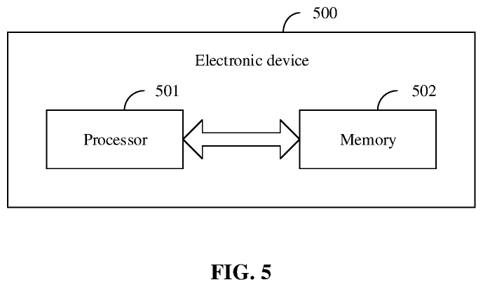

As illustrated in FIG. 5, embodiments of the disclosure further provide an electronic device 500, including a processor 501, a memory 502, and a program or instructions which are stored in the memory 502 and are executable by the processor 501. The program or instructions, when executed by the processor 501, implement each process according to the foregoing embodiments of the integrated circuit post-layout simulation method, and may achieve same technical effects, which will not be repeated herein.

It should be noted that the electronic device according to the embodiments of the disclosure includes the mobile electronic device and the non-mobile electronic device.

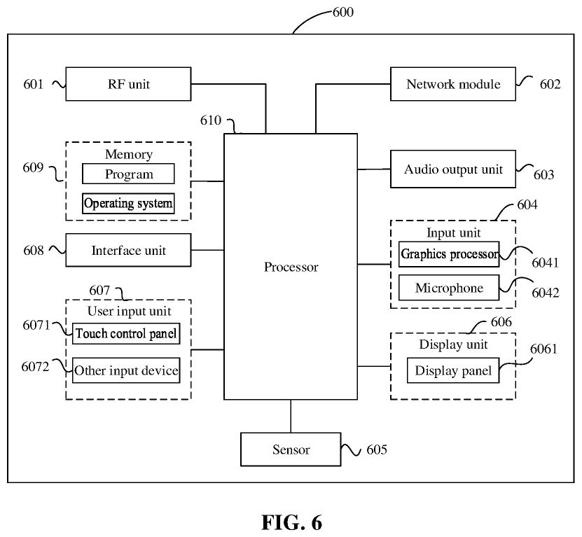

FIG. 6 illustrates a schematic structural diagram of hardware of an electronic device according to an embodiment of the disclosure.

The electronic device 600 includes, but is not limited to, a radio frequency (RF) unit 601, a network module 602, an audio output unit 603, an input unit 604, a sensor 605, a display unit 606, a user input unit 607, an interface unit 608, a memory 609, and a processor 610.

Those skilled in the art should understand that the electronic device 600 may further include a power supply (e.g. a battery) configured to power various components, which may be logically coupled to the processor 610 through a power management system for charging, discharging, and power consumption management functions through the power management system. The structure of the electronic device illustrated in FIG. 6 is not intended to limit the electronic device, and the electronic device provided by the disclosure may include more or fewer components than illustrated or may combine certain components or different component arrangements, which will not be repeated herein.

According to the electronic device provided in the embodiment, simulation may be performed by covering a pre-layout simulation netlist with the parasitic parameters of a target sub-element, omitting the circuit modules which do not need to be verified. The simulation can be carried out more pertinently, reducing the simulation time, and improving the simulation speed and verification efficiency of the integrated circuit.

It should be understood that, according to the embodiments of the disclosure, the input unit 604 may include a Graphics Processing Unit (GPU) 6041 and a microphone 6042. The GPU processes image data such as a still picture or video acquired by an image capturing device (e.g. a camera) in a video capturing mode or an image capturing mode. The display unit 606 may include a display panel 6061 which may be configured in the form of a liquid crystal display, an organic light emitting diode or the like. The user input unit 607 includes a touch panel 6071 and other input devices 6072. The touch panel 6071, further known as touch screen, may include two parts, i.e., a touch detection device and a touch controller. The other input devices 6072 may include but are not limited to a physical keyboard, a function key (e.g. a volume button, and a power button etc.), a trackball, a mouse and a joystick, which will not be repeated herein. The memory 609 may be configured to store a software program and various data including but not limited to an application program and an operating system. The processor 610 may be integrated with an application processor and a modem processor. The application processor is configured to process the operating system, a user interface, applications, and the like, and the modem processor is configured to process wireless communications. It should be understood that the modem processor may not be integrated into the processor 610.

Embodiments of the disclosure further provide a readable storage medium having stored thereon a program or instructions that, when executed by a processor, cause the processor to implement processes according to the embodiments for an integrated circuit post-layout simulation method, and achieve same technical effects, which will not be repeated herein.

The processor is a processor in an electronic device according to the foregoing embodiments. The readable storage medium includes a computer-readable storage medium, such as a computer Read-Only Memory (ROM), a Random Access Memory (RAM), a magnetic disk or an optical disk, etc.

Embodiments of the disclosure further provide a chip including a processor and a communication interface coupled to the processor. The processor is configured to run a program or instructions to implement processes according to the embodiments for an integrated circuit post-layout simulation method, and achieve same technical effect, which will not be repeated herein.

It should be understood that the chip according to the embodiment of the disclosure may further be referred to as a system-level chip, a system chip, s chip system, a system-on-chip or the like.

It should be noted that, the terms “including”, “comprising” or any other variation thereof are intended to be non-exclusive, so that a process, method, object or device which includes certain elements includes not only the elements but also other elements which are not explicitly listed, or the elements inherent to the process, method, object or device. Unless further defined, an element defined by the expression “includes a/an . . . ” does not preclude the situation that a process, method, object or device including the element includes another identical element. In addition, it should be noted that, the method and device according to the embodiments of the disclosure are not limited to implementing functions in the order shown or illustrated, and may further include implementing the functions in a substantially simultaneous manner or in reverse order depending on the related functions, for example, the method may be implemented in a different order than described, and various steps may further be added, omitted, or combined. In addition, the features described with reference to some embodiments may be combined in other embodiments.

From the foregoing description of the embodiments, those skilled in the art should understand that the method according to the foregoing embodiments may be implemented by means of software with a necessary common hardware platform, and of course further by means of hardware, but the former is preferred in many cases. Based on such understanding, the technical scheme of the disclosure in essence or the part thereof contributing to the prior art, may be implemented in the form of a computer software product. The computer software product is stored in a storage medium (e.g. ROM/RAM, magnetic disk and optical disk) and includes the instructions configured to enable a terminal (which may be a mobile phone, a computer, a server, or a network device, etc.) to implement the method according to the embodiments of the disclosure.

The embodiments of the disclosure are described above with reference to the drawings. However, the disclosure is not limited to the specific embodiments described above, and the embodiments described above are merely illustrative and not intended to limit the disclosure. Those of ordinary skill in the art may take many forms without departing from the spirit of the disclosure and the scope of the claims, which should fall within the scope of the disclosure.

1. An integrated circuit post-layout simulation method, comprising:
acquiring a pre-layout simulation netlist of a to-be-simulated circuit;
acquiring a first parasitic netlist of a target sub-element in the to-be-simulated circuit;
acquiring a simulation netlist of the to-be-simulated circuit using the first parasitic netlist and the pre-layout simulation netlist; and
simulating the simulation netlist.

2. The integrated circuit post-layout simulation method of claim 1, wherein, before acquiring the first parasitic netlist of the target sub-element in the to-be-simulated circuit, the integrated circuit post-layout simulation method further comprises:
determining the target sub-element in the to-be-simulated circuit.

3. The integrated circuit post-layout simulation method of claim 1, wherein acquiring the first parasitic netlist of the target sub-element in the to-be-simulated circuit comprises:
exporting a class definition language (CDL) netlist of the target sub-element;
determining a layout structure of the target sub-element and exporting a graphic data system (GDS) file according to the layout structure; and
obtaining the first parasitic netlist according to the CDL netlist and the GDS file.

4. The integrated circuit post-layout simulation method of claim 3, wherein obtaining the first parasitic netlist according to the CDL netlist and the GDS file comprises:
inputting the CDL netlist and the GDS file into an electronic design automation (EDA) tool, to enable the EDA tool to output the first parasitic netlist.

5. The integrated circuit post-layout simulation method of claim 1, wherein acquiring the simulation netlist of the to-be-simulated circuit using the first parasitic netlist and the pre-layout simulation netlist comprises:
changing an interface definition in the first parasitic netlist to obtain a second parasitic netlist, wherein the second parasitic netlist can be called by the pre-layout simulation netlist, and the simulation netlist comprises the second parasitic netlist and the pre-layout simulation netlist.

6. The integrated circuit post-layout simulation method of claim 5, wherein the pre-layout simulation netlist comprises a pre-layout simulation sub-netlist corresponding to the target sub-element, and the second parasitic netlist has a same interface definition as that of the pre-layout simulation sub-netlist.

7. The integrated circuit post-layout simulation method of claim 1, wherein simulating the simulation netlist comprises:
importing the simulation netlist into a simulator; and
calling the simulator to simulate the simulation netlist.

8. An integrated circuit post-layout simulation device, comprising:
a processor,
a memory, and
a program or instructions stored in the memory and executable in the processor, wherein the program or instructions, when executed by the processor, cause the processor to execute operations of:
acquiring a pre-layout simulation netlist of a to-be-simulated circuit;
acquiring a first parasitic netlist of a target sub-element in the to-be-simulated circuit;
acquiring a simulation netlist of the to-be-simulated circuit using the first parasitic netlist and the pre-layout simulation netlist; and
simulating the simulation netlist.

9. The integrated circuit post-layout simulation device of claim 8, wherein the processor is further caused to perform an operation of:
determining the target sub-element in the to-be-simulated circuit.

10. The integrated circuit post-layout simulation device of claim 9, wherein the processor is further caused to perform operations of:
exporting a class definition language (CDL) netlist of the target sub-element;
determining a layout structure of the target sub-element and export a graphic data system (GDS) file according to the layout structure; and
obtaining the first parasitic netlist according to the CDL netlist and the GDS file.

11. The integrated circuit post-layout simulation device of claim 10, wherein the processor is further caused to perform an operation of: inputting the CDL netlist and the GDS file into an electronic design automation (EDA) tool, to enable the EDA tool to output the first parasitic netlist.

12. The integrated circuit post-layout simulation device of claim 8, wherein the processor is further caused to perform an operation of:
changing an interface definition in the first parasitic netlist to obtain a second parasitic netlist, wherein the second parasitic netlist can be called by the pre-layout simulation netlist, and the simulation netlist comprises the second parasitic netlist and the pre-layout simulation netlist.

13. The integrated circuit post-layout simulation device of claim 8, wherein the processor is further caused to perform operations of:
importing the simulation netlist into an simulator; and
calling the simulator to simulate the simulation netlist.

14. The integrated circuit post-layout simulation device of claim 12, wherein the pre-layout simulation netlist comprises a pre-layout simulation sub-netlist corresponding to the target sub-element, and the second parasitic netlist has a same interface definition as that of the pre-layout simulation sub-netlist.

15. A non-transitory computer-readable storage medium having stored thereon a program or instructions that, when executed by a processor, cause the processor to implement the steps of an integrated circuit post-layout simulation method of claim 1.

16. A chip, comprising a processor and a communication interface coupled to the processor, wherein the processor is configured to execute a program or instructions to implement an integrated circuit post-layout simulation method, the integrated circuit post-layout simulation method comprising:
acquiring a pre-layout simulation netlist of a to-be-simulated circuit;
acquiring a first parasitic netlist of a target sub-element in the to-be-simulated circuit;
acquiring a simulation netlist of the to-be-simulated circuit using the first parasitic netlist and the pre-layout simulation netlist; and
simulating the simulation netlist.

17. The chip of claim 16, wherein, before acquiring the first parasitic netlist of the target sub-element in the to-be-simulated circuit, the integrated circuit post-layout simulation method further comprises:
determining the target sub-element in the to-be-simulated circuit.

18. The chip of claim 16, wherein acquiring the first parasitic netlist of the target sub-element in the to-be-simulated circuit comprises:
exporting a class definition language (CDL) netlist of the target sub-element;
determining a layout structure of the target sub-element and exporting a graphic data system (GDS) file according to the layout structure; and
obtaining the first parasitic netlist according to the CDL netlist and the GDS file.

19. The chip of claim 18, wherein obtaining the first parasitic netlist according to the CDL netlist and the GDS file comprises:
inputting the CDL netlist and the GDS file into an electronic design automation (EDA) tool, to enable the EDA tool to output the first parasitic netlist.

20. The chip of claim 16, wherein acquiring the simulation netlist of the to-be-simulated circuit using the first parasitic netlist and the pre-layout simulation netlist comprises:
changing an interface definition in the first parasitic netlist to obtain a second parasitic netlist, wherein the second parasitic netlist can be called by the pre-layout simulation netlist, and the simulation netlist comprises the second parasitic netlist and the pre-layout simulation netlist.
